(19) United States
(12) Patent Application Publication
(10) Pub. No.: US 2008/0145957 A1
(43) Pub. Date: Jun. 19, 2008

(54) WAFER TRANSFERRING ROBOT IN SEMICONDUCTOR DEVICE FABRICATION EQUIPMENTAND METHOD OF DETECTING WAFER WARPAGE USING THE SAME

(76) Inventors: Young-Sun Lee, Hwaseong-si (KR); Ho-Seong Kang, Seongnam-si (KR); Jung-Ho Kwak, Suwon-si (KR); Bong-su Kim, Suwon-si (KR); Young-Nam Kim, Suwon-si (KR); Yi-Su Lee, Yongin-si (KR)

Correspondence Address: F. CHAU & ASSOCIATES, LLC, 130 WOODBURY ROAD, WOODBURY, NY, 11797, US

(21) Appl. No.: 11/950,907

(22) Filed: Dec. 5, 2007

(30) Foreign Application Priority Data
Dec. 14, 2006 (KR) 2006-0127898

(51) Int. Cl. H01L 21/66; H01L 21/67

(52) U.S. Cl. 438/5; 414/217; 901/14; 901/40; 257/E21.521

(57) ABSTRACT

A wafer transferring robot in semiconductor device fabricating equipment and a method of detecting wafer warpage by using the wafer transferring robot are provided. In the realizing the wafer transferring robot to transfer a wafer, vacuum lines are formed to adsorb a plurality of regions of the wafer. Whether the wafer is warped or not and the extent of warpage are determined in real time, depending on whether the wafer is adsorbed by the vacuum lines. When no warpage occurs on the wafer or when the extent of warpage is slight, the wafer is allowed to be normally processed. When the extent of warpage is too serious to perform a normal process on the wafer, the wafer is previously processed as an error, thereby preventing the waste of time, cost and manpower caused by performing an unnecessary process.

### CROSS-REFERENCE TO RELATED APPLICATION

This application claims the benefit of Korean Patent Application No. 10-2006-0127898, filed Dec. 14, 2006, the disclosure of which is hereby incorporated herein by reference in its entirety.

### BACKGROUND OF THE INVENTION

1. Technical Field

The present disclosure relates to semiconductor device fabricating equipment, and more particularly, to a wafer transferring robot for transferring a wafer in semiconductor device fabricating equipment and to a method of detecting wafer warpage using the same.

2. Discussion of Related Art

Generally, a semiconductor device is fabricated by forming a plurality of circuit patterns by selectively and repeatedly performing various unit processes, such as, for example, a material layer deposition process, an etch process including photolithography, an impurity ion implantation and diffusion process, onto a wafer. Until a wafer is fabricated as a semiconductor device, the wafer is transferred to semiconductor device fabricating equipment which performs each unit process. For example, the wafer is transferred to a position where each process is performed or to a predetermined position which supports the performance of each process in the semiconductor device fabrication equipment.

For example, U.S. Pat. Nos. 6,533,530 and 6,379,095 describe structures and operation principles of a wafer transferring robot which is used to transfer a wafer to a process performing position.

The wafer transferring robot is installed in a transfer chamber. The wafer transferring robot sequentially and promptly loads and unloads a wafer between a load-lock chamber, an alignment chamber and a process chamber where a unit process is substantially performed, to fabricate a semiconductor device. Typically, the wafer transferring robot includes: a supporting shaft which is driven to move up and down and to rotate, a robot arm which is driven to rotate and be extendable based on the supporting shaft and a robot chuck which is positioned at the front end of the robot arm and which supports the bottom surface of a wafer. The robot arm is extendable by rotary power transferred from the supporting shaft and moves the robot chuck formed at the front end of the robot arm forward or backward.

The robot chuck is formed of a metal plate with a greater diameter than the diameter of the wafer, to support the wafer in a horizontal state. The robot chuck should be formed to support the center of gravity of the wafer. Therefore, for example, one side of the robot chuck may be connected to the robot arm and the other side thereof may be formed in a fork shape with at least one or more finger parts passing through the center of gravity of the wafer and protruding towards the outside of the edge of the wafer.

Accordingly, after the wafer is transferred onto a stage (or chuck) inside a process chamber by the wafer transferring robot, various unit processes for semiconductor device fabrication and other works for measurement and examination of process results are performed. Then, the wafer transferring robot transfers the wafer while adsorbing the bottom surface of the wafer.

However, as the size of a wafer becomes large to increase an output per unit area, a wafer warpage phenomenon may increasingly occur by stress caused during the unit processes. When the wafer is warped, a vacuum error may occur in the wafer transferring robot. As a result, the wafer transferring robot may not stably adsorb the wafer. That is, the wafer is adsorbed by using a vacuum line formed on the robot chuck of the wafer transferring robot. However, when the wafer is warped, as the vacuum line is off, it may not firmly adsorb the wafer. Further, when the wafer is not stably adsorbed on the wafer transferring robot due to the vacuum error, the wafer may be dropped while it is transferred to be loaded into or unloaded from the process chamber. Consequently, the dropped wafer may be broken, to thereby cause a loss of the wafer and contaminate the inside of the semiconductor device fabricating equipment by the broken pieces of the wafer.

Further, when the warped wafer is loaded into the process chamber, the unit process may not normally be performed. For example, with a photolithography process, as a difference in resolution may occur, a pattern may not be evenly formed throughout the whole wafer. Also, with a baking or cooling process, as the temperature may not uniformly distributed throughout the whole wafer, inferior quality may result. In addition to these difficulties in performing these unit processes, various measurement and tests relating to whether or not a success in the unit processes and the like may not be properly performed.

However, as it may not be accurately determined whether the aforementioned difficulties are caused by the warped wafer or by the hardware trouble of the semiconductor device fabricating equipment, it thus may not be easy to correct these difficulties.

### SUMMARY OF THE INVENTION

Exemplary embodiments of the present invention provide a wafer transferring robot in semiconductor device fabricating equipment, which detects wafer warpage.

Exemplary embodiments of the present invention provide a wafer transferring robot in semiconductor device fabricating equipment, which effectively detects the extent of wafer warpage.

Exemplary embodiments of the present invention provide a wafer transferring robot in semiconductor device fabricating equipment, which detects wafer warpage in real time.

Exemplary embodiments of the present invention provide a wafer transferring robot in semiconductor device fabricating equipment, which prevents a wafer from dropping, to prevent loss of the wafer and contamination of the equipment.

Exemplary embodiments of the present invention provide a wafer transferring robot in semiconductor device fabricating equipment, which enables a process, a measurement and a test to be smoothly performed.

Exemplary embodiments of the present invention provide a wafer transferring robot in semiconductor device fabricating equipment, which effectively detects whether a process error is caused by wafer warpage or hardware failure of the equipment.

In accordance with an exemplary embodiment of the present invention, a wafer transferring robot in semiconductor device fabricating equipment is provided. The wafer transferring robot includes a supporting shaft which is adapted to move vertically and rotates, a robot arm which is installed around the supporting shaft and rotates and is extendable from the supporting shaft and a robot chuck which is positioned at a front end of the robot arm and supports a bottom surface of a wafer to be held. The wafer transferring robot includes a plurality of vacuum lines which are formed in the robot chuck to vacuum-adsorb a plurality of regions of the wafer disposed on the robot chuck, and a vacuum in each of the vacuum lines is independently controlled. In addition, the wafer transferring robot includes a sensor which is positioned in each vacuum line in which the vacuum is independently controlled, senses whether a corresponding region of the wafer is vacuum-adsorbed through each vacuum line and a controller for determining the extent of warpage of the wafer by receiving a sensing signal from a corresponding sensor and for controlling whether the wafer is further processed or not.

In another exemplary embodiment of the present invention, a method of detecting wafer warpage by using a wafer transferring robot in semiconductor device fabricating equipment is provided. The method includes adsorbing a plurality of regions of a wafer held on a robot chuck of the wafer transferring robot through a plurality of vacuum lines which are formed in the robot chuck; sensing whether the wafer is adsorbed through each of the vacuum lines, by using an independent sensor which is positioned in each vacuum line and, as a result of the sensing by the sensor, determining that no warpage occurs in the wafer when the number of wafer regions adsorbed by the vacuum lines is equal to or more than a predetermined number, and determining that warpage occurs in the wafer when the number of wafer regions adsorbed by the vacuum lines is less than the predetermined number.

### BRIEF DESCRIPTION OF THE DRAWINGS

Exemplary embodiments of the present invention can be understood in more detail from the following description taken in conjunction with the attached drawings in which:

FIG. 1 illustrates semiconductor device fabricating equipment including a wafer transferring robot according to an exemplary embodiment of the present invention;

FIG. 2 is a perspective view of the wafer transferring robot illustrated in FIG. 1;

FIG. 3 is a plan view of a robot chuck illustrated in FIG. 2;

FIG. 4 illustrates a wafer held on the robot chuck, which is completely flat, without warpage;

FIG. 5 illustrates a wafer held on the robot chuck, in which a center region of the wafer is warped in a convex shape;

FIG. 6 illustrates a wafer held on the robot chuck, in which a right edge region of the wafer is warped;

FIG. 7 illustrates a wafer held on the robot chuck, in which a left edge region of the wafer is warped;

FIG. 8 illustrates a wafer held on the robot chuck, in which both edge regions of the wafer are warped in a concave shape;

FIG. 9 illustrates a wafer held on the robot chuck, in which the center region and the right edge region of the wafer are warped;

FIG. 10 illustrates a wafer held on the robot chuck, in which the center region and the left edge region of the wafer are warped; and

FIG. 11 is a flow chart for generally illustrating a method of detecting wafer warpage according to an exemplary embodiment of the present invention.

### DETAILED DESCRIPTION OF THE EXEMPLARY EMBODIMENTS OF THE INVENTION

This invention may, however, be embodied in many different forms and should not be construed as being limited to the exemplary embodiments set forth herein.

As the technology in the field of information and communication has been rapidly developed and the information media, such as computers, have been also rapidly popularized, semiconductor devices have been swiftly developed. Accordingly, a semiconductor device should operate at high speed and have high storage capacity in capability. Further, in accordance with the tendency of a semiconductor device towards high capacity and high integration density, the integration density of a semiconductor device has been increased more and more. In addition, the size of each unit element forming a semiconductor memory cell has been gradually reduced. Therefore, the technology for high integration density has been significantly developed to form a multi-layer structure within a restricted area.

To meet the aforementioned technology for high integration density, accuracy and preciseness should be provided in unit processes for semiconductor device fabrication. Typically, the unit process to fabricate a semiconductor device largely includes: an impurity ion implantation and diffusion process of implanting impurity ions of Group 3B (for example, B) or 5B (for example, P or As) into a semiconductor substrate, a thin film deposition process of forming a material layer on the semiconductor substrate, an etch process including photolithography of patterning the material layer formed by the thin film deposition process in a desired pattern, a chemical mechanical polishing (CMP) process of removing a step by polishing the wafer surface after an interlayer insulating layer and the like are deposited on the wafer surface, and a wafer cleaning process of removing impurities. Therefore, the aforementioned various unit processes are selectively and repeatedly performed to form a plurality of circuit patterns on the wafer surface, thereby fabricating a semiconductor device.

Each of the aforementioned various unit processes is performed in a process chamber in which wafers are processed by, for example, a batch type mode or a single type mode. The batch type mode processes may be about fifty wafers simultaneously. The single type mode processes wafers one by one. The batch type mode has the benefit of obtaining high throughput because about fifty wafers may be processed simultaneously. The single type mode has the benefit of realizing a very accurate process because wafers may be processed one by one.

Meanwhile, combining the benefit of the batch type mode and the advantage of the single type mode, a multi-chamber mode has been expansively used in the unit processes for semiconductor device fabrication. The multi-chamber mode uses a multi chamber where wafers are processed one by one to realize an accurate process and to produce improved throughput. The multi chamber includes a load-lock chamber where a cassette loading wafers is positioned, a process chamber where the aforementioned unit process is substantially performed, and a transfer chamber. In the multi chamber structure, the wafer is transferred between the load-lock chamber and the process chamber by the wafer transferring robot positioned in the transfer chamber.

Therefore, when the wafer is transferred onto a stage (or chuck) inside the process chamber by the wafer transferring robot, the bottom surface of the wafer is adsorbed by the wafer transferring robot so that the wafer is transferred for various unit processes for semiconductor device fabrication and for different work for measurement and examination of the results of the process.

However, as the size of a wafer becomes large to increase the productivity per unit area, a wafer warpage phenomenon increasingly occurs by the stress caused during the unit processes. When the wafer warpage occurs, a vacuum error may occur in the wafer transferring robot adsorbing the wafer and as a result, the wafer may drop to be broken during a series of wafer transferring processes of loading or unloading the wafer to or from the inside of the process chamber. Consequently, difficulties such as the inside of the semiconductor device fabricating equipment becoming contaminated by the broken wafer pieces as well as the wafer being lost may result. Moreover, when the warped wafer is loaded into the process chamber, the unit processes may not be performed normally or various measurement and tests of the wafer may not be performed smoothly. Consequently, the reliability of a semiconductor device and the productivity thereof may be decreased.

Therefore, exemplary embodiments of the present invention provide a wafer transferring robot which effectively detects wafer warpage in real time while a wafer is held in the wafer transferring robot, and a method of detecting the wafer warpage by using the wafer transferring robot. The wafer transferring robot is characterized by a number of vacuum lines and a number of sensors. In each vacuum line, a vacuum is independently controlled. Each sensor determines whether the wafer is absorbed through each vacuum line. Now, a wafer transferring robot and a method of detecting wafer warpage by using the wafer transferring robot according to exemplary embodiments of the present invention will be described, in detail, with reference to the drawings below.

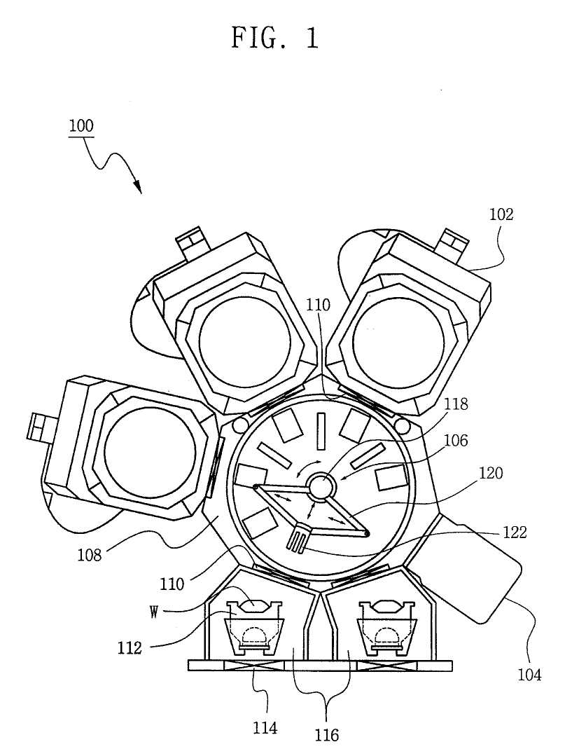

FIG. 1 illustrates semiconductor device fabricating equipment 100 including a wafer transferring robot according to an exemplary embodiment of the present invention.

In FIG. 1, the semiconductor device fabricating equipment 100, which is a cluster type including a multi chamber, includes a plurality of process chambers 102; an alignment chamber 104; a transfer chamber 108; and a plurality of load-lock chambers 116. In each process chamber, a unit process, such as a thin-film deposition process or an etch process of a wafer W, is performed. In the alignment chamber, a flat zone of the wafer on which the unit process is performed in each process chamber 102 is aligned in one direction. In the transfer chamber 108, a wafer transferring robot 106 is positioned to transfer the wafer W from the alignment chamber 104 to the process chamber 102. Each load-lock chamber 116 is operatively connected to the transfer chamber 108 and includes a slit valve 110 and a door 114. The slit valve 110 is formed at one side of the load-lock chamber 116 and is opened when the wafer transferring robot 106 enters.

### The door 114 allows a cassette loading a number of the wafers W to be in and out.

The wafer transferring robot 106 is a device for transferring a wafer between the process chamber 102, the alignment chamber 104, the transfer chamber 108 and the load-lock chamber 116. The wafer transferring robot 106 includes a supporting shaft 118 which is driven to move up and down and to rotate; a robot arm 120 which rotates and is extendable from the supporting shaft 118; and a robot chuck 122 supporting the bottom surface of a wafer. The wafer transferring robot 106 installed in the transfer chamber 108 sequentially and promptly loads or unloads a wafer between the load-lock chamber 116, the alignment chamber 104 and the process chamber 102, thereby obtaining high throughput compared to the single type mode and enabling a very accurate process to be performed.

In the semiconductor device fabricating equipment 100, the wafer transferring robot 106 detects wafer warpage and the extent of the wafer warpage while the wafer is held on the robot chuck 122. That is, as the robot chuck 122 includes a vacuum line for adsorbing a wafer, and a sensor (for example, vacuum sensor) for sensing whether the wafer is absorbed by the vacuum line, it is possible to detect the wafer warpage while a process of the wafer is performed. As the wafer warpage is detected in real time during the process is performed, it is possible to more smoothly perform the process and consequently to improve the reliability and productivity of a semiconductor device.

A detailed structure of the wafer transferring robot 106 and a method of detecting wafer warpage by the wafer transferring robot 106 will be described with reference to the drawings below.

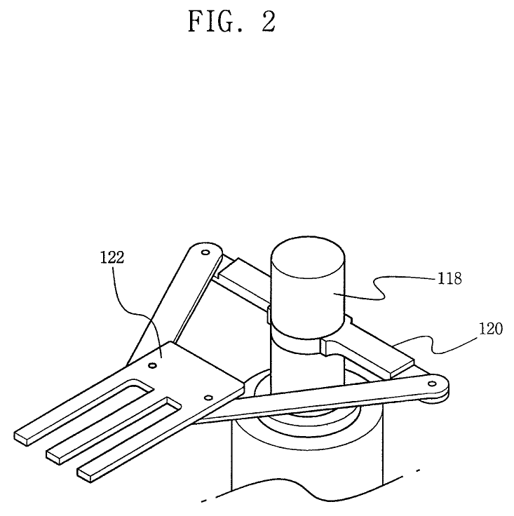

FIG. 2 is a perspective view of the wafer transferring robot 106 according to the exemplary embodiment of the present invention illustrated in FIG. 1.

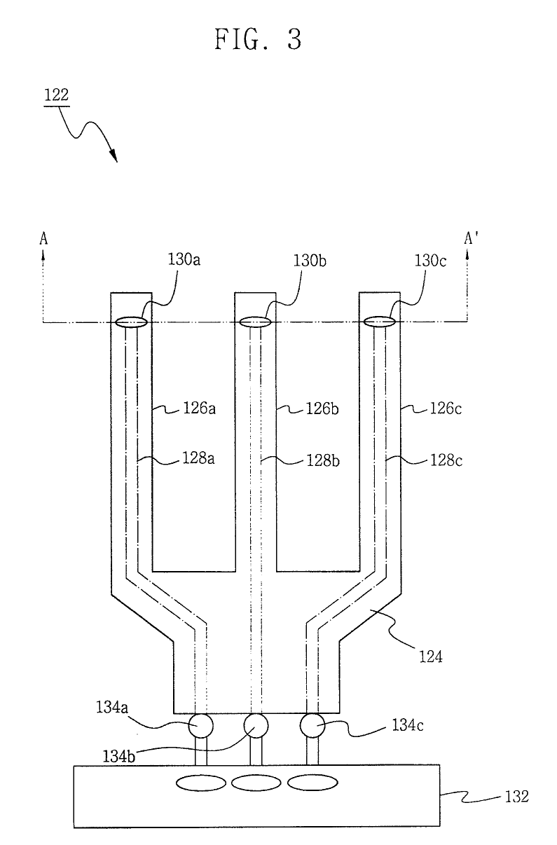

In FIG. 2, the wafer transferring robot 106 includes the supporting shaft 118 driven to move vertically and to rotate; the robot arm 120 formed around the supporting shaft 118, the robot arm rotating and being extendable from the supporting shaft 118; and the robot chuck 122 formed at a front end of the robot arm 120 for supporting the bottom surface of a wafer. The robot arm 120 is expandable by rotatory power transferred from the supporting shaft 118 and moves the robot chuck 122 formed at the front end of the robot arm 120 forward or backward. Then, the wafer is adsorbed by the vacuum line formed inside the robot chuck 122, to be transferred. The structure of the robot chuck 122 will be described, in detail, with reference to FIG. 3.

In FIG. 3, the robot chuck 122 is formed of a plate 124 for supporting the bottom surface of the wafer to be horizontally held. For example, the robot lo chuck 122 comprises the plate 124 and three fingers 126a, 126b and 126c which are formed at one side of the plate 124. The fingers 126a, 126b and 126c support the edge and center of the wafer, making it easy to take the wafer from another constitution and to transfer the wafer to another constitution and simultaneously minimizing a contact area with the bottom surface of the wafer. For example, the three fingers 126a, 126b and 126c of the robot chuck 122 are configured to support a center point of the wafer, a first point in a first direction from the center point, and a second point in a second direction opposite to the first direction. Therefore, the robot chuck 122 illustrated in FIG. 3 has a fork shape on the whole.

FIG. 3 presents the robot chuck 122 with all three fingers 126a, 126b and 126c. However, as the robot chuck 122 of FIG. 3 is just for one exemplary embodiment of the present invention, the number of fingers to support the bottom surface of the wafer may be changed.

A first vacuum line 128a, a second vacuum line 128b and a third vacuum line 128c are respectively formed in the first finger 126a, the second finger 126b and the third finger 126c of the robot chuck 122. The vacuum in each of the vacuum lines 128a, 128b and 128c is independently controlled by a solenoid valve 132 formed at the other side of the plate 124.

A first vacuum aperture 130a, a second vacuum aperture 130b and a third vacuum aperture 130c are respectively formed in the tip area of each of the first vacuum line 128a, the second vacuum line 128b and the third vacuum line 128c. In FIG. 3, each of the vacuum apertures 130a, 130b and 130c is formed in the tip area of each of the vacuum lines 128a, 128b and 128c but the number and position of the vacuum apertures may be changed.

A first vacuum sensor 134a, a second vacuum sensor 134b and a third vacuum sensor 134c are respectively mounted in the first vacuum line 126a, the second vacuum line 126b and the third vacuum line 126c in which the vacuum is controlled by the solenoid valve 132. Therefore, when a wafer is held on the robot chuck 122 having the above described structure, the first vacuum sensor 134a, the second vacuum sensor 134b and the third vacuum sensor 134c independently sense whether the wafer is adsorbed by the first vacuum aperture 130a, the second vacuum aperture 130b and the third vacuum aperture 130c which are respectively formed in the first finger 126a, the second finger 126b and the third finger 126c. Whether the wafer is warped or not and the extent of the wafer warpage are detected in detail.

A method of detecting wafer warpage by using the wafer transferring robot according to the exemplary embodiment of the present invention will be described in detail.

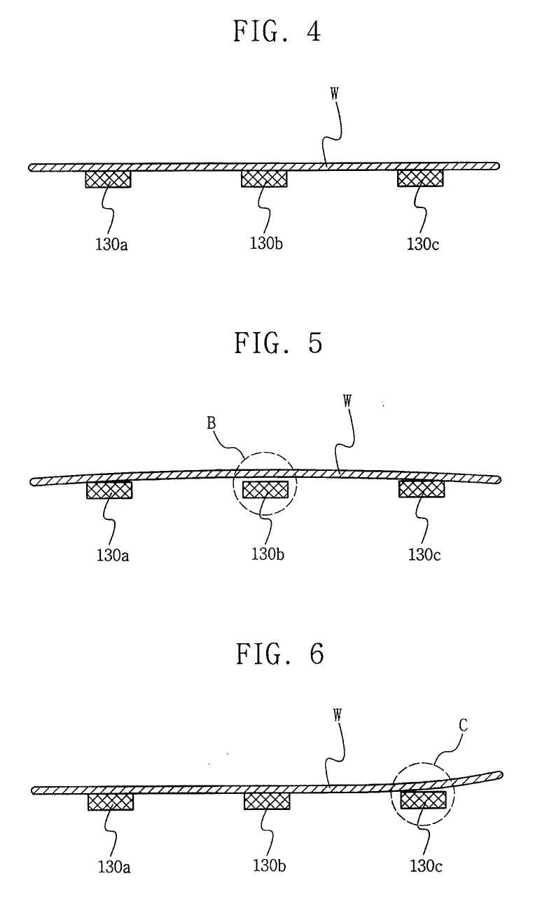

FIGS. 4 through 10 are sectional views taken along Line A-A′ of the robot chuck 122 of FIG. 3, illustrating the wafer which is held on the robot chuck 122.

As illustrated in FIG. 4, when the wafer is completely flat, without warpage, the wafer is perfectly adsorbed to the first vacuum aperture 130a, the second vacuum aperture 130b and the third vacuum aperture 130c which are respectively formed in the first vacuum line 128a, the second vacuum line 128b and the third vacuum line 128c of the robot chuck 122. When the wafer is perfectly adsorbed to the three vacuum apertures 130a, 130b and 130c, all of the first vacuum sensor 134a, the second vacuum sensor 134b and the third vacuum sensor 134c which are respectively connected to the three vacuum apertures 130a, 130b and 130c are turned on, as indicated in [Table 1] below. When the vacuum sensing results by the three vacuum sensors 134a, 134b and 134c are applied to a controller, the controller determines that the wafer is in “good” state without warpage. Therefore, a normal process is performed on the wafer in “good” state.

TABLE 1

| First | Second | Third | |
|---|---|---|---|
| vacuum | vacuum | vacuum | Wafer |
| sensor | sensor | sensor | condition |
| on | On | on | Good |

FIGS. 5 through 7 illustrate a wafer which is not adsorbed to any one of the three vacuum apertures 130a, 130b and 130c formed in the robot chuck 122.

In FIG. 5, a wafer with a center region being warped in a convex shape is held on the robot chuck 122. As illustrated in FIG. 5, when the wafer is warped in the convex shape, the wafer is not adsorbed to the second vacuum aperture 130b which is formed to adsorb the wafer center region, among the three vacuum apertures 130a, 130b and 130c formed in the robot chuck 122. (see reference mark “B” in FIG. 5)

When the wafer is not adsorbed to the second vacuum aperture 130b positioned in the center of the three vacuum apertures 130a, 130b and 130c formed in the robot chuck 122, the second vacuum sensor 124b connected to the second vacuum line 128b which adsorbs the wafer center region, among the three vacuum sensors 134a, 134b and 134c respectively connected to the vacuum lines 128a, 128b and 128c, is turned off as indicated in [Table 2] below. The vacuum sensing results by the vacuum sensors 134a, 134b and 134c are applied to the controller. Then, as illustrated in FIG. 5, when the wafer is not adsorbed to the second vacuum aperture 130b only which is formed to absorb the wafer center region, among the three vacuum apertures 130a, 130b and 130c formed in the robot chuck 122, the controller determines that, even though the wafer center region is substantially warped in the convex shape, the extent of warpage is slight. As a result, the controller does not process the wafer as an error and determines that the wafer is in “good” state. Therefore, a normal process is performed on the wafer with the center region being slightly warped.

TABLE 2

| First | Second | Third | |
|---|---|---|---|
| vacuum | vacuum | vacuum | Wafer |
| sensor | sensor | sensor | condition |
| on | Off | on | good |

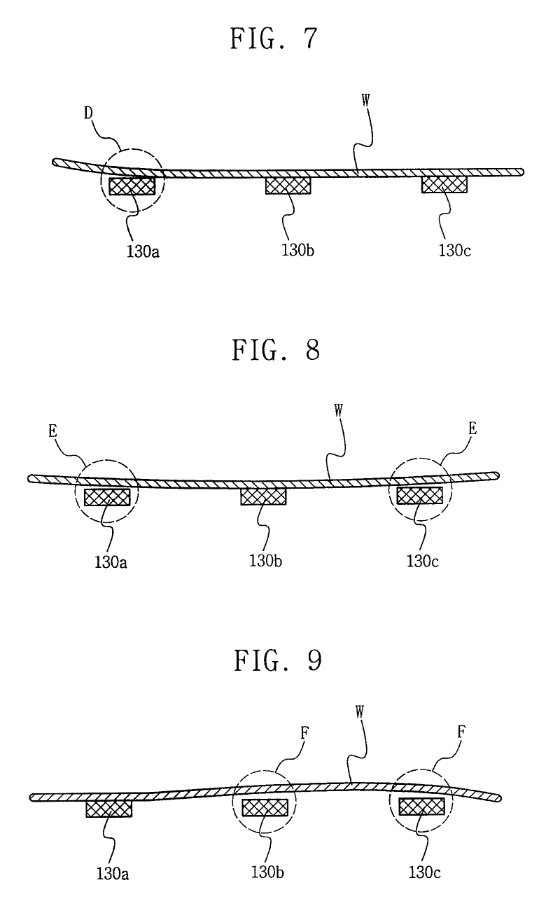

FIG. 6 illustrates a wafer held on the robot chuck 122, in which a right edge region of the wafer (on the right relative to the drawing) is warped; and FIG. 7 illustrates a wafer held on the robot chuck 122, in which a left edge region of the wafer (on the left relative to the drawing) is warped.

As illustrated in FIG. 6, when the right edge region of the wafer is warped in a concave shape, the wafer is not adsorbed to the third vacuum aperture 130c which is formed to adsorb the right edge region of the wafer, among the three vacuum apertures 130a, 130b and 130c formed in the robot chuck 122. (see reference mark “C” in FIG. 6)

When the wafer is not adsorbed to the third vacuum aperture 130c which is positioned on the right, among the three vacuum apertures 130a, 130b and 130c formed in the robot chuck 122, the third vacuum sensor 134c connected to the third vacuum line 128c which is formed to adsorb the wafer right region, among the three vacuum sensors 134a, 134b and 134c respectively connected to the vacuum lines 128a, 128b and 128c, is turned off as indicated in [Table 3] below. The vacuum sensing results by the vacuum sensors 134a, 134b and 134c are applied to the controller. Then, as illustrated in FIG. 6, when the wafer is not adsorbed to the third vacuum aperture 130c only which is formed to absorb the wafer right region, among the three vacuum apertures 130a, 130b and 130c formed in the robot chuck 122, the controller determines that, even though the right edge region of the wafer is substantially warped, the extent of warpage is slight. As a result, the controller does not process the wafer as an error and determines that the wafer is in “good” state. Therefore, a normal process is performed on the wafer with the right region being slightly warped.

TABLE 3

| First | Second | Third | |
|---|---|---|---|
| vacuum | vacuum | vacuum | Wafer |
| sensor | sensor | sensor | condition |
| on | On | off | good |

As illustrated in FIG. 7, when the left edge region of the wafer is warped in a concave shape, the wafer is not adsorbed to the first vacuum aperture 130a which is formed to adsorb the left edge region of the wafer, among the three vacuum apertures 130a, 130b and 130c formed in the robot chuck 122. (see reference mark “D” in FIG. 7)

When the wafer is not adsorbed to the first vacuum aperture 130a which is positioned on the left, among the three vacuum apertures 130a, 130b and 130c formed in the robot chuck 122, the first vacuum sensor 134a connected to the first vacuum line 128a which is formed to adsorb the wafer left region, among the three vacuum sensors 134a, 134b and 134c respectively connected to the vacuum lines 128a, 128b and 128c, is turned off as indicated in [Table 4] below. The vacuum sensing results by the vacuum sensors 134a, 134b and 134c are applied to the controller. Then, as illustrated in FIG. 7, when the wafer is not adsorbed to the first vacuum aperture 130a only which is formed to absorb the wafer left region, among the three vacuum apertures 130a, 130b and 130c formed in the robot chuck 122, the controller determines that, even though the left edge region of the wafer is substantially warped, the extent of warpage is slight. As a result, the controller does not process the wafer as an error and determines that the wafer is in “good” state. Therefore, a normal process is performed on the wafer with the left region being slightly warped.

TABLE 4

| First | Second | Third | |
|---|---|---|---|
| vacuum | vacuum | vacuum | Wafer |
| sensor | sensor | sensor | condition |
| off | on | on | good |

As illustrated in FIGS. 5 through 7, when the wafer is not adsorbed to any one of the three vacuum apertures 130a, 130b and 130c formed in the robot chuck 122, the vacuum sensor connected to the corresponding vacuum aperture is turned off. When any one of the vacuum sensors respectively connected to the three vacuum apertures is turned off, the wafer is substantially warped in the center region, the right or left region based on the center region. However, since the extent of the wafer warpage is determined as being slight, the controller does not consider the wafer as an error. That is, the controller determines the “good” state with respect to the wafer with slight warpage, so that the wafer is normally processed.

FIGS. 8 through 10 respectively illustrate a wafer which is not adsorbed to two or more vacuum apertures among the three vacuum apertures 130a, 130b and 130c formed in the robot chuck 122.

FIG. 8 illustrates a wafer held on the robot chuck 122, in which both edge regions of the wafer are warped in a concave shape. As illustrated in FIG. 8, when both edge regions of the wafer are warped in the concave shape, the wafer is not adsorbed to the first vacuum aperture 130a and the third vacuum aperture 130c which are formed to adsorb the left and right edge regions of the wafer, among the three vacuum apertures 130a, 130b and 130c formed in the robot chuck 122. (see reference mark “E” in FIG. 8)

When the wafer is not adsorbed to the first vacuum aperture 130a and the third vacuum aperture 130c which are positioned at the left and right, among the three vacuum apertures 130a, 130b and 130c formed in the robot chuck 122, the first vacuum sensor 134a and the third vacuum sensor 134c respectively connected to the first vacuum line 128a and the third vacuum line 128c which are formed to adsorb the left and right regions of the wafer, among the three vacuum sensors 134a, 134b and 134c respectively connected to the vacuum lines 128a, 128b and 128c, are turned off as indicated in [Table 5] below. The vacuum sensing results by the vacuum sensors 134a, 134b and 134c are applied to the controller. Then, as illustrated in FIG. 8, when the wafer is not adsorbed to the first vacuum aperture 130a and the third vacuum aperture 130c which are formed to absorb the left and right regions of the wafer, among the three vacuum apertures 130a, 130b and 130c formed in the robot chuck 122, the controller determines that the wafer is seriously warped and determines that the wafer is in “bad” state. Therefore, no further process is performed on the wafer.

TABLE 5

| First | Second | Third | |
|---|---|---|---|
| vacuum | vacuum | vacuum | Wafer |
| sensor | sensor | sensor | condition |
| off | on | off | bad |

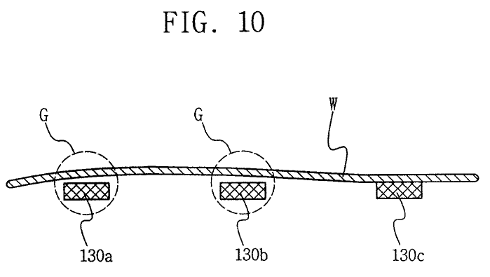

FIGS. 9 and 10 respectively illustrate a wafer held on the robot chuck 122, in which the center region and either edge region of the wafer are warped in a convex shape.

As illustrated in FIG. 9, when the center and right edge region of the wafer are warped in the convex shape, the wafer is not adsorbed to the second vacuum aperture 130b and the third vacuum aperture 130c which are formed to respectively adsorb the center region and the right edge region of the wafer, among the three vacuum apertures 130a, 130b, 130c formed in the robot chuck 122. (See reference mark F in FIG. 9)

When the wafer is not adsorbed to the second vacuum aperture 130b and the third vacuum aperture 130c which are formed to respectively adsorb the center region and the right edge region of the wafer, among the three vacuum apertures 130a, 130b, 130c formed in the robot chuck 122, the second vacuum sensor 134b and the third vacuum sensor 134c respectively connected to the second vacuum line 128b and the third vacuum line 128c, among the three vacuum sensors 134a, 134b and 134c respectively connected to the vacuum lines 128a, 128b and 128c, are turned off as indicated in [Table 6] below. The vacuum sensing results by the vacuum sensors 134a, 134b and 134c are applied to the controller. Then, as illustrated in FIG. 9, when the second vacuum sensor 134b and the third vacuum sensor 134c are turned off because the wafer is not adsorbed to the second vacuum aperture 130b and the third vacuum aperture 130c which are formed to absorb the center and right edge regions of the wafer, among the three vacuum apertures 130a, 130b and 130c formed in the robot chuck 122, the controller determines that the wafer is seriously warped and determines that the wafer is in “bad” state. Therefore, no further process is performed on the wafer.

TABLE 6

| First | Second | Third | |
|---|---|---|---|
| vacuum | vacuum | vacuum | Wafer |
| sensor | sensor | sensor | condition |
| on | off | off | bad |

As illustrated in FIG. 10, when the center and left edge regions of the wafer are warped in the convex shape, the wafer is not adsorbed to the first vacuum aperture 130a and the second vacuum aperture 130b which are formed to respectively adsorb the left edge region and center region of the wafer, among the three vacuum apertures 130a, 130b, 130c formed in the robot chuck 122. (See reference mark G in FIG. 10)

When the wafer is not adsorbed to the first vacuum aperture 130a and the second vacuum aperture 130b which are formed to respectively adsorb the left edge region and the center region of the wafer, among the three vacuum apertures 130a, 130b, 130c formed in the robot chuck 122, the first vacuum sensor 134a and the second vacuum sensor 134b respectively connected to the first vacuum line 128a and the second vacuum line 128b which are formed to absorb the left edge region and the center region of the wafer, among the three vacuum sensors 134a, 134b and 134c respectively connected to the vacuum lines 128a, 128b and 128c, are turned off as indicated in [Table 7] below. The vacuum sensing results by the vacuum sensors 134a, 134b and 134c are applied to the controller. Then, as illustrated in FIG. 10, when the first vacuum sensor 134a and the second vacuum sensor 134b are turned off because the wafer is not adsorbed to the first vacuum aperture 130a and the second vacuum aperture 130b which are formed to absorb the left edge region and center region of the wafer, among the three vacuum apertures 130a, 130b and 130c formed in the robot chuck 122, the controller determines that the wafer is seriously warped and determines that the wafer is in “bad” state. Therefore, no further process is performed on the wafer.

TABLE 7

| First | Second | Third | |
|---|---|---|---|
| vacuum | vacuum | vacuum | Wafer |
| sensor | sensor | sensor | condition |
| off | off | on | bad |

As illustrated in FIGS. 5 through 7, when the wafer is not adsorbed to only any one of the three vacuum apertures 130a, 130b and 130c formed in the robot chuck 122, although warpage substantially occurs on the wafer, the extent of warpage is determined as being slight. Therefore, the wafer is not subject to error processing. That is, the wafer is determined as “good”, so that a normal process is performed on the wafer. However, as illustrated in FIGS. 8 through 10, when the wafer is not adsorbed to two or more of the three vacuum apertures 130a, 130b and 130c formed in the robot chuck 122, the extent of warpage is determined as being serious. Thus, the wafer is determined as “bad”, so that any further process is not performed on the wafer.

As described above, in exemplary embodiments of the present invention to realize the wafer transferring robot to transfer a wafer, the vacuum lines and the vacuum apertures for adsorbing the wafer are formed in the three fingers which are configured to respectively support the center point of the wafer, the first point in the first direction from the center position, and the second point in the second direction opposite to the first direction. The wafer warpage and the extent of warpage are determined by using the vacuum sensors which are turned on/off depending on whether the wafer is adsorbed to the vacuum apertures. In exemplary embodiments of the present invention, when two or more vacuum sensors are turned on as the wafer is adsorbed to two or more vacuum apertures, among the three vacuum apertures respectively formed in the three fingers, although warpage substantially occurs on the wafer, the extent of warpage is determined as being slight and therefore the normal process is performed on the wafer.

A method of detecting wafer warpage according to another exemplary embodiment of the present invention will be described with reference to FIGS. 2, 3 and 11.

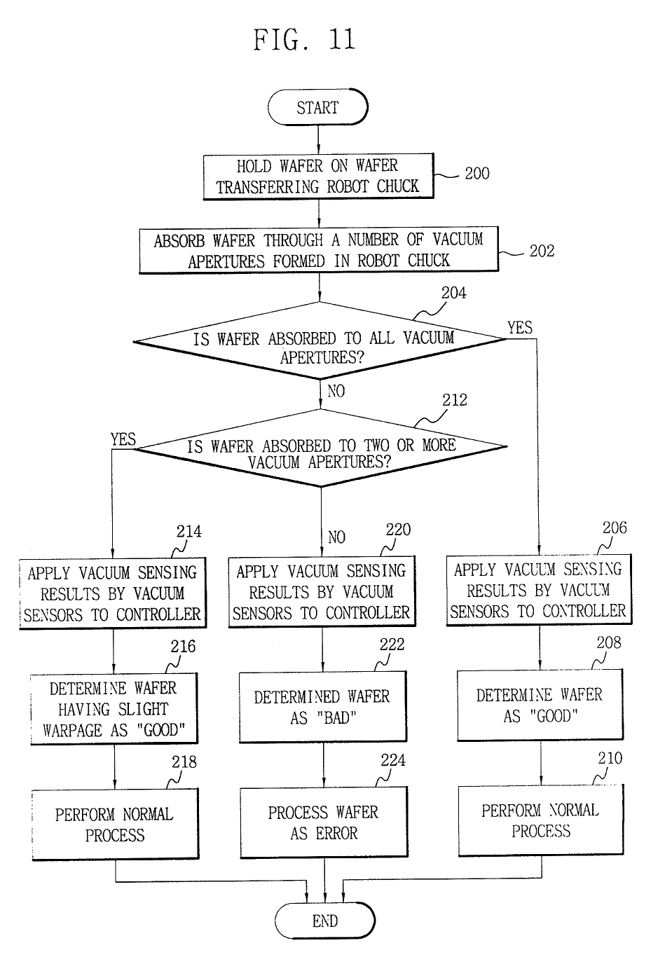

In FIG. 11, in step 200, a wafer is held on the robot chuck 122 of the wafer transferring robot 106 illustrated in FIG. 3.

In step 202, the solenoid valve 132 is opened to open each of the vacuum lines 128a, 128b and 128c respectively formed in the first finger 126a, the second finger 126b and the third finger 126c of the robot chuck 122. The bottom surface of the wafer is adsorbed through the vacuum apertures 130a, 130b and 130c respectively formed in the tip areas of the vacuum lines 128a, 128b and 128c. Then, the first finger 126a, the second finger 126b and the third finger 126c are formed to respectively support the center point of the wafer, the first point in the first direction from the center point and the second point in the second direction opposite to the first direction. Accordingly, the center point of the wafer, the left edge region and the right edge region of the wafer from the center point are adsorbed through the vacuum apertures 130a, 130b and 130c formed in the three fingers 126a, 126b and 126c.

In step 204, it is checked whether the wafer is adsorbed to a number of the vacuum apertures 130a, 130b and 130c. As a result of check, when the wafer is adsorbed to all of the first vacuum aperture 130a, the second vacuum aperture 130b and the third vacuum aperture 130c, the first vacuum sensor 134a, the second vacuum sensor 134b and the third vacuum sensor 134c which are respectively connected to the vacuum lines 128a, 128b and 128c are turned on. Subsequently, in step 206, the vacuum sensing results by the vacuum sensors 134a, 134b and 134c are applied to the controller. Then, in step 208, the wafer is determined as being in the good state, without warpage. Therefore, in step 210, a normal process is performed on the wafer. For example, when the wafer transferring robot loads the wafer on a stage inside the process chamber, a typical unit process, such as a material layer deposition process or a photolithography process, is performed on the wafer. Or, when the aforementioned unit process of the wafer is completed, a measurement and examination process to test whether the unit process is successful is performed on the wafer.

Meanwhile, as a result of the check in the step 204, when the wafer is not adsorbed to all of the vacuum apertures 130a, 130b and 130c, in step 212 it is checked whether the wafer is adsorbed to two or more vacuum apertures, among the total vacuum apertures 130a, 130b and 130c. As the result, when the wafer is adsorbed to two vacuum apertures among the total vacuum apertures 130a, 130b and 130c, two vacuum sensors which are connected to the vacuum apertures to which the wafer is adsorbed are turned on while the other vacuum sensor which is connected to the vacuum aperture to which the wafer is not adsorbed is turned off. In step 214, the vacuum sensing results by the vacuum sensors 134a, 134b and 134c are applied to the controller. In step 216, the extent of warpage on the wafer is determined according to the vacuum sensing results by the vacuum sensors 134a, 134b and 134c. That is, as the wafer is not adsorbed to all of the first vacuum aperture 130a, the second vacuum aperture 130b and the third vacuum aperture 130c formed in the robot chuck 122, it is not determined that the wafer is completely flat. In other words, when the wafer is adsorbed to two or more of the total vacuum apertures 130a, 130b and 130c, it is considered that warpage substantially occurs on the center region, the left edge region or the right edge region of the wafer. However, as it is determined that the extent of warpage is determined as being slight, the wafer is determined as “good”, without being processed as an error. Accordingly, in step 218, a normal process is performed on the wafer with slight warpage. For example, when the wafer transferring robot loads the wafer on a stage inside the process chamber, a typical unit process, such as a material layer deposition process or a photolithography process, is performed on the wafer. Or, when the aforementioned unit process of the wafer is completed, a measurement and examination process to test whether the unit process is successful is performed on the wafer.

Meanwhile, as a result of the check in the step 212, when the wafer is not adsorbed to two or more vacuum apertures among the total vacuum apertures 130a, 130b and 130c formed in the robot chuck, one vacuum sensor which is connected to the vacuum aperture to which the wafer is adsorbed is turned on while the other two vacuum sensors which are connected to the vacuum apertures to which the wafer is not adsorbed are turned off.

Subsequently, in step 220, the vacuum sensing results by the vacuum sensors 134a, 134b and 134c are applied to the controller. Then, in step 222, the extent of warpage of the wafer is determined according to the vacuum sensing results by the vacuum sensors 134a, 134b and 134c. That is, as the wafer is not adsorbed to two or more vacuum apertures among the first vacuum aperture 130a, the second vacuum aperture 130b and the third vacuum aperture 130c formed in the robot chuck 122, the extent of warpage is determined as seriously “bad”. Then, in step 224, the wafer determined as “bad” is processed as an error, so that no further process is performed on this wafer. Further, a display of an LCD monitor and the like may display that the wafer is determined as “bad” or an alarm may be provided to notify the wafer error.

As described above, in accordance with an exemplary embodiment of the present invention relating to the wafer transferring robot, which transfers a wafer in the semiconductor device fabricating equipment, and the method of detecting the wafer warpage using the same, whether the wafer is warped and the extent of warpage are detected in real time while the wafer is held in the transferring robot. That is, in realizing the wafer transferring robot to transfer a wafer, the vacuum apertures to adsorb at least three or more wafer regions are formed in the robot chuck where the wafer is substantially held. When two or more wafer regions are adsorbed to the vacuum apertures, it is determined that the wafer is not warped or the extent of warpage is very slight even though the wafer is warped, to allow the wafer to be normally processed. When two or more wafer regions are not adsorbed through the vacuum apertures, it is determined that the extent of warpage is serious, to process the wafer as an error and not to allow the wafer to be further processed.

As the size of a wafer becomes large, the wafer warpage phenomenon may increasingly occur due to the stress generated during unit processes. In exemplary embodiments of the present invention, when a wafer is held in the wafer transferring robot, the warpage of the wafer is detected in real time. As a result, as a trouble wafer which cannot be subject to a normal process is filtered, the present invention may prevent the difficulties of the conventional technology caused by the wafer warpage. (For example, when a wafer is not stably adsorbed on a wafer transferring robot, the wafer may drop to be broken during a wafer transferring process of loading or unloading the wafer in or from the inside of the process chamber, resulting in the loss of wafers or the contamination inside the semiconductor device fabricating equipment by the broken wafer pieces.)

Further, when a wafer being seriously warped is loaded into the process chamber, unit processes are not normally and properly performed and various measurement and test processes to be carried out on the wafer are not smoothly performed, thereby possibly resulting in the deterioration of the reliability and productivity of the semiconductor device. However, with exemplary embodiments of the present invention, as the wafer which cannot be normally processed is previously detected as an error, time is prevented from being wasted by performing any unnecessary process and accordingly expenses and manpower are prevented from being wasted.

Further, with exemplary embodiments of the present invention, it is accurately determined whether the reason for performing an abnormal process is caused by the wafer warpage or the hardware trouble of the semiconductor device fabricating equipment. Therefore, exemplary embodiments of the present invention may provide more prompt and accurate approaches for preventing the above-mentioned difficulties of the conventional art.

In the exemplary embodiments of the present invention, the vacuum sensor which is one of indirect sensors is presented as the sensor for sensing whether the wafer held on the robot chuck is adsorbed. However, this exemplary embodiment is provided as a teaching example to help in understanding the present invention. Therefore, various sensors which sense whether the wafer is adsorbed are applicable, in addition to the vacuum sensor. For example, a touch sensor which is on/off depending on whether the wafer is adsorbed to the vacuum line, or a non-touch sensor, such as a photo sensor using light, may be applied.

In realizing the wafer transferring robot to transfer a wafer of exemplary embodiments of the present invention, as the vacuum lines for adsorbing at least three or more wafer regions are formed in the robot chuck where the wafer is held, and whether the wafer is adsorbed by the vacuum lines is sensed, the wafer warpage and the extent of warpage are detected in real time while the wafer is held on the robot chuck. Therefore, as the wafer warpage and the extent of warpage are detected in real time while the wafer is held on the robot chuck, and the trouble wafer which cannot be normally processed is filtered, the reliability and productivity of the semiconductor device may be improved.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A wafer transferring robot in semiconductor device fabricating equipment, comprising:
a supporting shaft adapted to be driven to move vertically and to rotate;
a robot arm installed around the supporting shaft, the robot arm rotable and being extendable from the supporting shaft;
a robot chuck positioned at a front end of the robot arm for supporting a bottom surface of a wafer to be held;
a plurality of vacuum lines formed in the robot chuck to vacuum-adsorb a plurality of regions of the wafer disposed on the robot chuck, a vacuum in each of the vacuum lines being independently controlled;
a sensor positioned in each vacuum line in which the vacuum is independently controlled, the sensor sensing whether a corresponding region of the wafer is vacuum-adsorbed through each vacuum line; and
a controller for determining the extent of warpage of the wafer by receiving a sensing signal from a corresponding sensor and for controlling whether or not to proceed with a process to be performed on the wafer.

2. The wafer transferring robot according to claim 1, wherein the robot chuck is formed to support a center region of the wafer, a first region in a first direction from the center region, and a second region in a second direction opposite to the first direction.

3. The wafer transferring robot according to claim 1, wherein the robot chuck is formed to support a center region of the wafer, an edge region in a first direction from the center region, and another edge region in a second direction opposite to the first direction.

4. The wafer transferring robot according to claim 1, wherein the sensor is a vacuum sensor which is turned on/off, depending on whether the wafer is adsorbed through each vacuum line.

5. The wafer transferring robot according to claim 1, wherein the sensor is a touch sensor which is turned on/off, depending on whether the wafer is adsorbed through each vacuum line.

6. The wafer transferring robot according to claim 1, wherein the vacuum of each vacuum line is independently controlled by a solenoid valve.

7. The wafer transferring robot according to claim 1, further comprising: one, or two or more vacuum apertures formed in a tip of each vacuum line.

8. A wafer transferring robot in semiconductor device fabricating equipment, comprising:
a supporting shaft adapted to be driven to move vertically and to rotate;
a robot arm installed around the supporting shaft, the robot arm rotable and being extendable from the supporting shaft;
a robot chuck positioned at a front end of the robot arm, the robot chuck having a plate for supporting a bottom surface of a wafer to be held, and a plurality of fingers formed at one side of the plate;
a plurality of vacuum lines formed through the plate and the fingers forming the robot chuck to vacuum-adsorb a plurality of regions of the wafer disposed on the robot chuck, a vacuum in each of the vacuum lines being independently controlled;
a sensor positioned in each vacuum line in which the vacuum is independently controlled, the sensor sensing whether a corresponding region of the wafer is vacuum-adsorbed through each vacuum line; and
a controller for determining the extent of warpage of the wafer by receiving a sensing signal from a corresponding sensor and for controlling whether or not to proceed with a process to be performed on the wafer.

9. The wafer transferring robot according to claim 8, wherein the fingers are formed to support a center region of the wafer, a first region in a first direction from the center region, and a second region in a second direction opposite to the first direction.

10. The wafer transferring robot according to claim 8, wherein the fingers are formed to support a center region of the wafer, an edge region in a first direction from the center region, and another edge region in a second direction opposite to the first direction.

11. The wafer transferring robot according to claim 8, wherein the sensor is a vacuum sensor which is turned on/off, depending on whether the wafer is adsorbed through each vacuum line.

12. The wafer transferring robot according to claim 8, wherein the sensor is a touch sensor which is turned on/off, depending on whether the wafer is adsorbed through each vacuum line.

13. The wafer transferring robot according to claim 8, wherein the vacuum of each vacuum line is independently controlled by a solenoid valve.

14. The wafer transferring robot according to claim 8, further comprising: one, or two or more vacuum apertures formed in a tip of each vacuum line.

15. A method of detecting wafer warpage by using a wafer transferring robot in semiconductor device fabricating equipment, comprising:
adsorbing a plurality of regions of a wafer held on a robot chuck of the wafer transferring robot through a plurality of independent vacuum lines formed in the robot chuck;
sensing whether the wafer is adsorbed through each vacuum line, by using a sensor formed in each vacuum line;
determining whether the wafer has warpage or no warpage from a sensing result from each sensor, wherein when the number of regions of the wafer which are adsorbed by the vacuum lines is equal to or more than a predetermined number, the wafer is determined to have no warpage, and wherein when the number of regions of the wafer which are adsorbed by the vacuum lines is less than the predetermined number, the wafer is determined to have warpage.

16. The method according to claim 15, wherein the adsorbing of the regions of the wafer is performed by adsorbing a center region of the wafer, a first region in a first direction from the center region, and a second region in a second direction opposite to the first direction, through the vacuum lines.

17. The method according to claim 15, wherein the adsorbing of the regions of the wafer is performed by adsorbing a center region of the wafer, an edge region in a first direction from the center region, and another edge region in a second direction opposite to the first direction, through the vacuum lines.

18. The method according to claim 15, wherein whether the wafer is adsorbed by the vacuum lines is sensed by any one of a vacuum sensor and a touch sensor, both which are on/off depending on whether the wafer is adsorbed by the vacuum lines.

19. The method according to claim 15, wherein the vacuum of the vacuum lines is independently controlled by a solenoid valve.

20. The method according to claim 15, further comprising:
controlling a subsequent process to be performed on the wafer when it is determined from the sensing result of each sensor that there is no warpage; or controlling that no more subsequent processes be performed on the wafer when it is determined from the sensing result of each sensor that the wafer has warpage.
